(19) United States
(12) Patent Application Publication
(10) Pub. No.: US 2023/0326947 A1
(43) Pub. Date: Oct. 12, 2023

(54) INTEGRATED CIRCUIT INCLUDING A METAL PILLAR IN CONTACT WITH A SILICON REGION ON AN OHMIC COUPLING REGION, AND CORRESPONDING MANUFACTURING METHOD

(71) Applicant: STMicroelectronics (Crolles 2) SAS, Crolles (FR)

(72) Inventors: Magali GREGOIRE, Crolles (FR); Joel SCHMITT, Chapareillan (FR)

(73) Assignee: STMicroelectronics (Crolles 2) SAS, Crolles (FR)

(21) Appl. No.: 18/131,543

(22) Filed: Apr. 6, 2023

(30) Foreign Application Priority Data
Apr. 11, 2022 (FR) 2203300

(51) Int. Cl. H01L 27/146

(52) U.S. Cl. CPC H01L 27/14634; H01L 27/1469; H01L 27/14636

(57) ABSTRACT

An integrated circuit includes at least one silicon region and at least one metal pillar in contact with the at least one silicon region at an ohmic coupling region. The at least one metal pillar is formed by: depositing a layer of titanium on the at least one silicon region; depositing atomic layers of titanium nitride on the layer of titanium; and annealing at a temperature of between 715° C. and 815° C. for a period of between 5 seconds and 30 seconds. This forms a titanium silicide for the ohmic coupling region in a volume having the appearance of a spherical cap or segment.

### PRIORITY CLAIM

This application claims the priority benefit of French Application for Patent No. 2203300, filed on Apr. 11, 2022, the content of which is hereby incorporated by reference in its entirety to the maximum extent allowable by law.

### TECHNICAL FIELD

Embodiments and implementations relate to integrated circuits and to the methods for manufacturing integrated circuits, in particular the formation of ohmic coupling regions between a metal pillar and a silicon region.

### BACKGROUND

Ohmic coupling regions, usually referred to as “silicide”, are created by a method, usually called “siliconizing”, of diffusing metals towards the silicon, or of diffusing silicon towards the metal, or of diffusing the two species towards each other, so as to form a metal silicide compound in a contact zone between the metal and the silicon. The ohmic coupling regions make it possible to reduce the resistance of the contact as well as the Schottky barrier, usually referenced in certain types of devices, such as imager devices.

In imager technologies of the global shutter type in particular, there is a correlation between the final efficiency of the products and the performance of the contacts (i.e., the low resistance and the reliability) with semiconducting regions of the pixels.

The emergence of novel three-dimensional technologies with illumination by the rear face referred to in the art as 3D Backside Illumination “3D-BSI” introduces greater requirements in terms of performance of the contacts to meet the new requirements of the products. This is because, in advanced 3D-BSI imager technologies, a high dark current and high resistances of the contacts on the gates in the zone of the pixel are known to be a problem limiting the performance of the pixel. It is known that dark current is sensitive to the doping level of the p-n junction, to the density of the crystalline defects in the silicon, but also to the quality of the ohmic coupling regions in the zone of the pixel.

Moreover, the conventional contact techniques are typically designed for n⁺ doped silicon wells and do not make it possible to obtain satisfactory results on the p⁺ doped regions and on gate regions belonging to the pixels.

Thus, there is a need for offering high-performance contacts for improving the global performances and the final efficiency of the products, in particular integrated circuits of imagers.

Furthermore, the inventors have found that it is preferable to avoid relatively high concentrations of oxygen in the metal silicides of the ohmic coupling regions that are suspected of participating in the generation of the dark current.

### SUMMARY

According to one aspect, in this regard an integrated circuit including at least one silicon region and at least one metal pillar in contact with said silicon region on an ohmic coupling region is proposed, wherein the ohmic coupling region comprises titanium silicide in a volume having the appearance of a spherical segment.

Preferably, said volume has the appearance of a spherical cap. It should be noted that a spherical cap is a particular case of spherical segment, and the form of a spherical cap corresponds substantially to the form of an optical lens.

In this context, reference to “a volume having the appearance of a spherical segment (or of a spherical cap)” will be understood to mean that a spherical-segment form (or spherical-cap form) can be recognized in a microscope observation (for example of the scanning electron microscopy type, and/or of the “S/TEM” transmission type, optionally accompanied by an energy diffusion X-ray “EDX” detection), i.e., for example, that an interpolation of the curvature of the sphere including the spherical segment (or the spherical cap) can be obtained at a finite value with a maximum likelihood.

In other words, given the physical nature, for example obtained by diffusion of material, of the volume of the ohmic coupling region, the reading of the words “a volume having the appearance of a spherical segment/cap” will not be limited to a purely mathematical object having a perfectly regular form and/or according to abstract considerations such as a curvature of infinite radius defining a volume delimited by planes.

Thus, compared with the conventional implementations of ohmic coupling regions having typically thin and flat appearances, here the appearance is thick. The spherical-segment appearance of the volume comprising the titanium silicide represents a diffusion of the materials with better, more extensive and more uniform isotropy. One consequence of the better isotropy, of the greater extent and of the better uniformity of the metal-silicide volume is a reduction in the contact resistance. For example, the resistance of the contact on a p⁺ doped silicon or polysilicon region can be between 30% and 50% of the resistance of a conventional contact having a structure and size similar to this contact, but a conventionally thin and flat ohmic coupling region. For example, the resistance of the contact on an n⁺ doped silicon or polysilicon region may be of the order of 80% of the resistance of a conventional contact having a structure and size similar to this contact, but a conventionally thin and flat ohmic coupling region.

According to one embodiment, the volume of the ohmic coupling region has the appearance of a spherical segment with a base disc radius of between 45 nanometers and 57 nanometers, and a height of between 14 nanometers and 26 nanometers.

Geometrically, a spherical segment is the solid defined by the volume of a globe lying between two parallel planes. The two parallel planes are separated by a distance referred to as the height, and divide the globe into a large base disc by the plane closest to the center of the globe, and into a small base disc by the plane furthest away from the center of the globe. “Spherical cap” means the case of a spherical segment with a single base disc when one of the two planes is tangent to the globe. The large base disc corresponds physically to the surface located at the bottom of the metal pillar. The height corresponds in practice to the maximum thickness (vertically) of the volume, substantially located at the center of the base discs.

According to one embodiment, the ohmic coupling region comprises oxygen atoms in proportions below 10% (in atomic percentage).

According to one embodiment, the ohmic coupling region comprises silicon atoms in proportions between 60% and 80% (in atomic percentages).

These embodiments correspond to a titanium silicide composition having better purity than the conventional compositions, and a stoichiometry closer to titanium disilicide TiSi₂ than the conventional compositions.

According to one embodiment, the ohmic coupling region comprises a layer of titanium nitride and the layer of titanium silicide, the thickest part of the layer of titanium nitride having a thickness of between 5 nanometers and 6 nanometers, and the thickest part of the layer of titanium silicide having a thickness of between 9 nanometers and 20 nanometers.

According to one embodiment, the integrated circuit furthermore includes a matrix of photosensitive pixels, wherein the silicon region is located in the matrix of photosensitive pixels.

The ohmic coupling region has performances in terms of resistance and reliability adapted to the constraints of the latest imager technologies. In particular, the performance of the ohmic coupling region makes it possible to help to reduce the dark current of the pixels (i.e., a parasitic current generated by a photodiode in the absence of light).

According to one embodiment, said photosensitive pixels include transistors comprising transfer gates and/or transistor gates and/or vertical gates buried in a substrate, and the silicon region is a transfer gate or a gate of a transistor or a vertical gate buried in the substrate.

According to one embodiment, the silicon region is p⁺ doped silicon with a concentration of p dopants greater than 10¹⁸ atoms per cubic centimeter.

According to one embodiment, the integrated circuit is assembled in a three-dimensional integration of two superimposed integrated circuit chips.

There again, the ohmic coupling region has performance in terms of resistance and reliability adapted to the constraints of the latest technologies of three-dimensional integration of two superimposed chips, for example for imagers of a 3-Dimensional Backside Illumination “3D-BSP” type.

According to another aspect, a method for manufacturing an integrated circuit is also proposed, comprising a formation of at least one silicon region and a formation of at least one metal pillar in contact with said silicon region on an ohmic coupling region, the formation of the metal pillar comprising: depositing a layer of titanium on the silicon region; depositing atomic layers of titanium nitride on the titanium layer; and annealing at a temperature of between 715° C. and 815° C. for a period of between 5 seconds and 30 seconds.

The steps of forming the metal pillar according to this aspect make it possible, in particular, to obtain the particular structure of the ohmic coupling region comprising titanium silicide in a volume having the appearance of a spherical segment, or preferentially the appearance of a spherical cap, defined above.

In particular, the step of depositing titanium nitride, by a technique of depositing atomic layers (usually an atomic layer deposition “ALD”), forms a dense layer rich in nitrogen (nitride). The annealing step has a higher temperature and a longer time than typical conditions of manufacture of conventional contacts and makes it possible, in combination with the depositing of the dense layer of titanium nitride rich in nitrogen, a diffusion of the materials with better, more extensive and more uniform isotropy so as to form the titanium silicide in a volume having the appearance of a spherical segment.

Furthermore, the step of depositing titanium nitride by ALD helps to obtain oxygen contents below 10% in the ohmic coupling region, and helps to obtain silicon contents of between 60% and 80% in the ohmic coupling region.

According to one embodiment, the formation of the metal pillar comprises a step of surface preparation by a remote gas plasma of nitrogen trifluoride and ammonia on the silicon region, before the step of depositing the layer of titanium.

A remote plasma is an electrically discharged plasma, usually obtained by means of a metal gate placed in the reaction chamber between the generation of the plasma and the device being treated, and making it possible to capture the electrical charges of the plasma. The preparation step makes it possible to remove a layer of “native” oxide on the surface of said silicon region, without electrically disturbing the surface being treated, thus contributing to the improvement in the resistance of the contact.

According to one embodiment, the layer of titanium deposited has a thickness of between 17.5 nanometers and 40 nanometers, and the layer of titanium nitride deposited has a thickness of between 3 nanometers and 6 nanometers.

This makes it possible in particular to form the ohmic coupling region in which the thickest part of the layer of titanium nitride has a thickness of between 5 nanometers and 6 nanometers, and the thickest part of the layer of titanium silicide has a thickness of between 9 nanometers and 20 nanometers, as defined above.

According to one embodiment, the formation of said at least one silicon region is included in a manufacture of a matrix of photosensitive pixels.

According to one embodiment, the manufacture of the matrix of photosensitive pixels comprises formation of transistors including transfer gates and/or transistor gates and/or vertical gates buried in a substrate, said at least one silicon region being a transfer gate or a gate of a transistor or a vertical gate buried in the substrate.

According to one embodiment, the formation of the silicon region comprises an implantation of p-type dopants in silicon, with a concentration greater than 10¹⁸ atoms of dopant per cubic centimeter.

According to one embodiment, the step of depositing the layer of titanium comprises a use of an electrostatic plate for holding a semiconductor wafer including the integrated circuit.

This is because it was serendipitously discovered by the inventors, during experimental implementations of the method described above, that the use of an electrostatic plate provided for holding the wafer contributes, surprisingly, to reducing the dark current of the photosensitive pixels. A theory that can explain this phenomenon is that the electrostatic charges of the plate would reduce the quantity of dipoles in crystalline defects of the photosensitive regions of the pixels.

According to one embodiment, the method furthermore comprises an assembly of the integrated circuit in a three-dimensional integration of two superimposed chips.

### BRIEF DESCRIPTION OF THE DRAWINGS

Other advantages and features of the invention will emerge from the examination of the detailed description of embodiments and implementations, which are in no way limitative, and the accompanying drawings, on which:

FIGS. 1A, 1B and 1C illustrate respectively a method for forming metal pillars in contact with a silicon region on an ohmic coupling region;

FIG. 2A illustrates a method for improving the performance of the contacts between the metal pillars and the silicon regions;

FIG. 2B illustrates a transmission electron microscopy “TEM” image of a structure obtained by the method described above in relation to FIG. 2A;

FIG. 2C shows measurements of proportions of various materials of the structure obtained by the method along the axis CC in FIG. 2B;

FIG. 3 is a comparative table illustrating certain structural parameters;

FIG. 4 schematically illustrates a photosensitive pixel belonging to a matrix of pixels in an image capture device;

FIG. 5 illustrates a backside illumination BSI imager technology using a three-dimensional integration of two superimposed chips; and

FIG. 6 illustrates measurements of the dark current of the pixels for imager devices'

### DETAILED DESCRIPTION

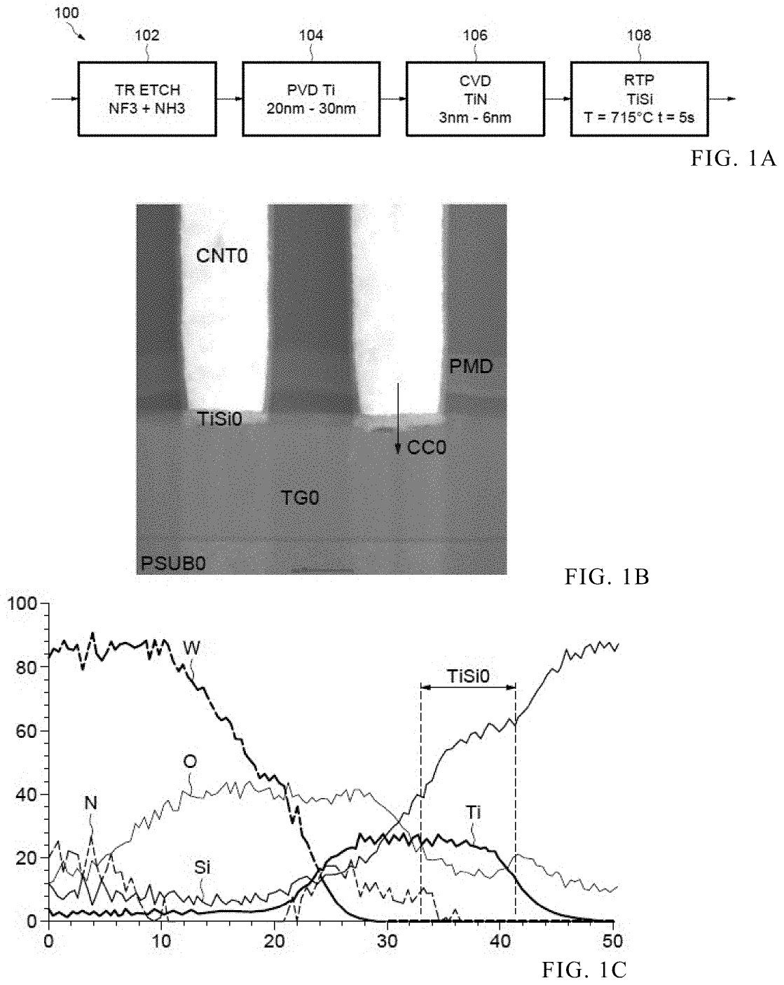

FIGS. 1A, 1B and 1C, for comparative reference, illustrate respectively a method 100 for forming metal pillars CNT0 in contact with a silicon region TG0 on an ohmic coupling region TiSiO (FIG. 1A); an image of the structure obtained by the method 100 coming from transmission electron microscopy (FIG. 1B) and a measurement of the materials content along the axis CC0 of FIG. 1B (FIG. 1C).

The method 100 comprises a step 102 of preparing the formation of the metal pillars CNT0. The step 102 comprises an etching of trenches TR ETCH in one or more pre-metal dielectric layers PMD located, in the finished integrated circuit product, between a semiconductor part PSUB0, TG0 and the first level of metal in an interconnection grating (usually “BEOL”, standing for “back end of line”). The semiconducting part PSUB0, TG0 includes elements to be contacted electrically with the pillars CNT0, for example a polycrystalline silicon transistor gate TG0. The etched trenches have a substantially cylindrical form, with a diameter of between 90 nm (nanometers) and 115 nm, and a depth reaching the silicon elements to be contacted.

The step 102 may furthermore comprise a “degassing” under argon plasma and a surface preparation by exposing the etched device, and in particular the silicon in the openings of the trenches, to a remote plasma, based on the ionization of nitrogen trifluoride and ammonia gases “NF₃+NH₃”.

In a step 104, a first “barrier” layer of titanium Ti is deposited on the uncovered surfaces of the etched device (i.e., in particular on the sides and in the bottom of the trenches). The layer of titanium is, for example, deposited by a conventional physical vapor deposition (PVD) technique with a substantially constant thickness of between 20 nm and 30 nm.

In a step 106, a second “barrier” layer of titanium nitride TiN is deposited on top of the layer of titanium Ti. The layer of titanium nitride TiN is, for example, deposited by a conventional chemical vapor deposition (CVD) technique on a substantially constant thickness of between 3 nm and 6 nm.

In a step 108, a conventional annealing, for example called rapid thermal process (RTP), heats the device thus obtained at a temperature T=715° C. (degrees Celsius) for a time t=5 s (seconds). The annealing diffuses the titanium of the barrier layers in the silicon region TG0, so as to form a titanium silicide TiSiO compound. A diffusion of the silicon atoms also occurs in the silicon layer TG0. The metal silicide compound is intended to improve the quality of the ohmic coupling between the pillar CNT0 and the silicon TG0 (i.e., intended to reduce the resistance of the coupling).

Finally, the trenches which are covered on their bottoms and sides with the barrier layers are filled with a metal, typically tungsten, and levelling techniques (for example a chemical mechanical planarization (CMP)) remove the excess metal on the top of the pre-metal dielectric layer PMD.

It can be seen on the image in FIG. 1B, in this example a transmission electron microscopy TEM of the structure obtained by the method 100, that the volume of titanium silicide has a flat appearance, substantially cylindrical, at a diameter of between 90 nm and 115 nm and a thickness of less than 8 nm.

FIG. 1C, showing the measurement of the contents (i.e., the concentrations reported in atomic percentages) of the various materials of the structure obtained by the method 100 along the axis CC0 in FIG. 1B, for example obtained by energy-dispersive X-ray spectroscopy (EDX). It can be seen in FIG. 1C that the layer of metal silicide TiSiO, located between approximately 32 nm and 41 nm on the axis CC0, includes approximately 20% oxygen atoms.

The low thickness (less than 8 nm) and the high oxygen content (approximately 20%) of the layer of metal silicide TiSiO contribute to the forces limiting the required reduction in the resistance of the contact between the metal pillar CNT0 and the silicon gate TG0.

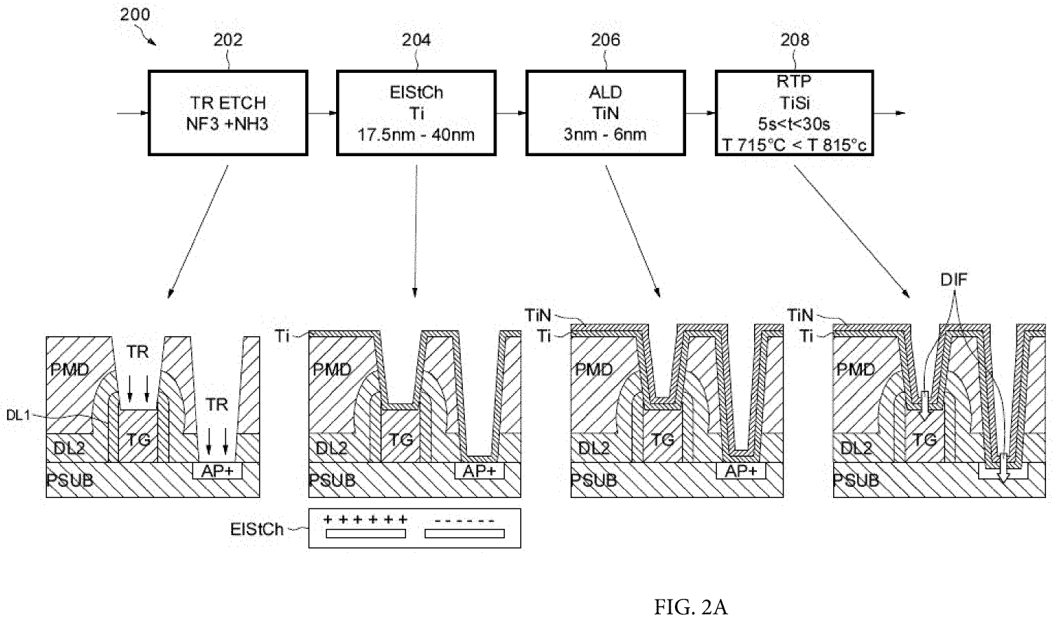

FIG. 2A illustrates a method 200 for improving the performance of the contacts between the metal pillars and the silicon regions TG, P+, in particular with regard to electrical resistance of the contacts.

The method 200 comprises a preparation step 202 similar to the preparation step 102 of the reference method. The step 202 thus comprises an etching of trenches TR ETCH in pre-metal dielectric layers PMD, DL2, DL1 located on a semiconducting part PSUB, TG, AP+. The semiconducting part is manufactured in advance on a semiconductor substrate PSUB, typically made from silicon, and includes a transfer gate TG, structurally assimilatable to a transistor gate, and a highly doped region AP+ implanted in the substrate PSUB, for example an anode of a photodiode.

“Highly doped region” means a doped region the dopant concentration of which is higher than 10¹⁸ atoms per cubic centimeter.

The transfer gate TG and the anode AP+ are intended to be contacted by metal pillars and trenches TR are formed opposite these silicon regions TG, AP+. The etched trenches have a substantially cylindrical form, with a diameter of between 90 nm and 115 nm, and a depth reaching the transfer gate TG and the anode AP+ elements to be contacted.

The step 202 may also further comprise a “degassing” under argon plasma and a surface preparation by exposure of the etched device, and in particular the silicon in the openings of the trenches, to an offset plasma based on the ionization of the nitrogen and ammonia gases NF₃+NH₃.

In a step 204, a first so-called “barrier” layer of titanium Ti is deposited on the uncovered surfaces of the etched device (i.e., in particular on the sides and in the bottom of the trenches TR). The layer of titanium Ti is advantageously deposited by a physical vapor deposition PVD technique in a reactor provided with an electrostatic holding plate ElStCh (usually “electrostatic chuck”) of the substrate PSUB.

The electrostatic holding chuck ElStCh is a device adapted for holding the substrate PSUB of the integrated circuit (at this step of the method 200, the integrated circuit belongs to a wafer in the reactor chamber allowing the deposition 204 of the layer of titanium Ti. The water is held by an electrostatic force, i.e. the Coulomb force, occurring in response to alternating voltages of the order of −400 V (volts) and +400 V in internal electrodes of the plate.

Furthermore, the layer of titanium Ti is deposited over a substantially constant thickness of between 17.5 nm and 40 nm.

In a step 206, a second so-called “barrier” layer of titanium nitride TiN is deposited on the layer of titanium Ti. The layer of titanium nitride TiN is deposited by an atomic layer deposition (ALD) technique over a constant thickness of between 3 nm and 6 nm.

The atomic layer deposition technique ALD is a particular variant of chemical vapor deposition CVD, producing in the precise case of a deposit of titanium nitride TiN a very pure material, with very high density and perfectly stoichiometric, which confers thereon a significantly greater impermeability to the ambient atmosphere (in particular to oxygen) compared with conventional chemical vapor deposition methods.

Thus, the step 206 of atomic layer deposition ALD results in a formation of the layer of titanium nitride TiN that is denser and purer than the conventional CVD methods. Consequently, oxygen atom impurities are present in proportions of less than 10%, or even less than 5%, in the atomic layer deposition ALD of titanium nitride TiN, while the oxygen may have a proportion of the order of 20% in conventional CVD techniques.

In a step 208, a longer and/or hotter annealing than during the conventional step 108 but which may also be termed rapid thermal process RTP, heats the device thus obtained at a temperature T of between 715° C. and 815° C. (715° C.≤T≤815° C.) for a time t of between 5 s (seconds) and 30 s (5 s≤t≤30 s). Preferentially, the temperature T is between 740° C. and 790° C. and the time t is between 10 s and 30 s. Even more preferentially, the temperature T is between 760° C. and 770° C., for example 765° C., and the time t is between 10 s and 20 s, for example 15 s.

The annealing diffuses the titanium of the barrier layers in the silicon regions TG, AP+, so as to form a titanium silicide compound TiSiₓ (FIG. 2B) in an ohmic coupling region RCPL (FIG. 2B) that is particularly advantageous for the performance of the contact.

This is because the technique of atomic layer deposition ALD 206 of the titanium nitride TiN forms a dense nitrogen-rich layer (nitride), and the annealing step 208 at a higher temperature and for a longer time than conditions of the reference method 100 allow a diffusion of the materials with better isotropy, more extensive and more uniform, so as to form the titanium silicide in a volume having the appearance of a spherical segment, or preferentially a spherical cap. In this regard reference will be made to the following description in relation to FIG. 2B.

Finally, the trenches covered on their bottoms and their edges with the barrier layers are filled with a metal, for example tungsten, and the excess metal is removed by levelling techniques to form the metal pillars CNT (FIG. 2B).

FIG. 2B illustrates a transmission electron microscopy “TEM” image of the structure obtained by the method 200 described above in relation to FIG. 2A, the common elements bear the same references and will not all be detailed once again.

The metal pillars CNT are in contact with silicon regions, for example a transfer gate TG and a region of the substrate PSUB, on an ohmic coupling region RCPL obtained at the end of the annealing step 208. The ohmic coupling region RCPL has a volume having the appearance of a spherical cap and comprises in particular titanium silicide TiSiₓ.

The volume of the ohmic coupling region RCPL may comprise the layer of titanium nitride TiN and the titanium silicide composition TiSiₓ.

A spherical segment SgmtS, geometrically shown alongside the microscopy image in FIG. 2B, is the solid defined by the volume of a globe B lying between two parallel planes P1, P2. The two parallel planes P1, P2 are separated by a distance referred to as height h. The plane P1 closest to the center C of the globe B divides the globe into a large base disc of radius r1, while the plane P2 furthest away from the center C of the globe B divides the globe into a small base disc of radius r2.

A spherical cap CltS, geometrically shown alongside the microscopy image in FIG. 2B, corresponds to the smaller of the two divisions of a sphere S by a plane P. The intersection between the sphere S and the plane P forms the base circle, of radius r, of the cap CltS. It is considered that the words “spherical cap” CltS also designate the closed volume (i.e., the solid) delimited by the surface of the cap CltS and the base disc of the base circle. The spherical cap is also the particular case of the spherical segment of a single (large) base disc (i.e., the particular case where the plane P2 is tangent to the globe B).

Given the physical nature obtained by the diffusion of the ohmic coupling region RCPL, the form of the volume of the ohmic coupling region RCPL is not perfectly regular as its mathematical definition would mean. Mathematical abstractions will also be excluded, such as limit cases of the plane P tangent to the sphere S (for the definition of the spherical cap CltS), of sphere S or globe B of infinite radius R, or of two identical planes P1, P2 (for the definition of the spherical segment SgmtS).

Thus, in order to avoid the extrapolation of a substantially cylindrical form with fine thickness to a case of a spherical segment defined by planes P1, P2 close to the center C of the globe B and by a height h equal to the thickness of the cylinder, an appearance of a spherical segment “recognizable” by a radius r1 of the large base disc less than three quarters (¾) of the radius R of the globe B is defined.

As on the microscopy image of FIG. 2B, an appearance of a spherical segment is recognizable in an observation of the integrated circuit (i.e., it is in particular possible to measure the radius R of the globe B, the radius r1 of the large base disc (the case of the spherical cap), and optionally the radius r2 of the small base disc and the height h of the spherical segment).

For example, in practice, if the volume of the ohmic coupling region RCPL has the appearance of a spherical cap, the radius of the base circle (or disc) r is between 45 nanometers and 57 nanometers, and the height h is between 14 nanometers and 26 nanometers.

In a similar manner, if the volume of the ohmic coupling region RCPL has the appearance of a spherical segment, the radius of the large base disc r1 is between 45 nanometers and 57 nanometers, and the height h is between 14 nanometers and 26 nanometers.

The height h may, for example, correspond to the layer of titanium nitride TiN having a thickness of between 5 nm and 6 nm in its thickest part, and the layer of titanium silicide TiSiₓ having a thickness of between 9 mm and 20 nm in its thickest part. The layer of titanium nitride TiN is nevertheless of substantially constant thickness.

FIG. 2C shows the measurement of the proportions of the various materials of the structure obtained by the method 200 along the axis CC in FIG. 2B, for example also obtained by energy dispersion X-ray spectroscopy “EDX”. It can be seen on FIG. 2C that the layer of metal silicide TiSiₓ, located between approximately 100 nm and 110 nm on the axis CC, includes less than 5% oxygen atoms.

Consequently, and from another point of view, the ohmic coupling region RCPL includes silicon atoms in proportions of between 60% and 80% and titanium atoms in proportions of between 20% and 40%, which is advantageously close to stoichiometry of the titanium disilicide TiSi₂.

The consequence of the cap or spherical segment appearance of the volume of the coupling region RCPL, reflecting better isotropy, a greater extent and better uniformity of the diffusion of the metal silicide, as well as the low oxygen content in the metal silicide TiSiₓ, is a reduction in the resistance of the contact. For example, the resistance of the contact may be between 30% and 50% of the resistance of the reference contact TiSiO described in relation to FIGS. 1A, 1B and 1C, in the case where the silicon region is p⁺ doped, and around 80% if the silicon region is n⁺ doped.

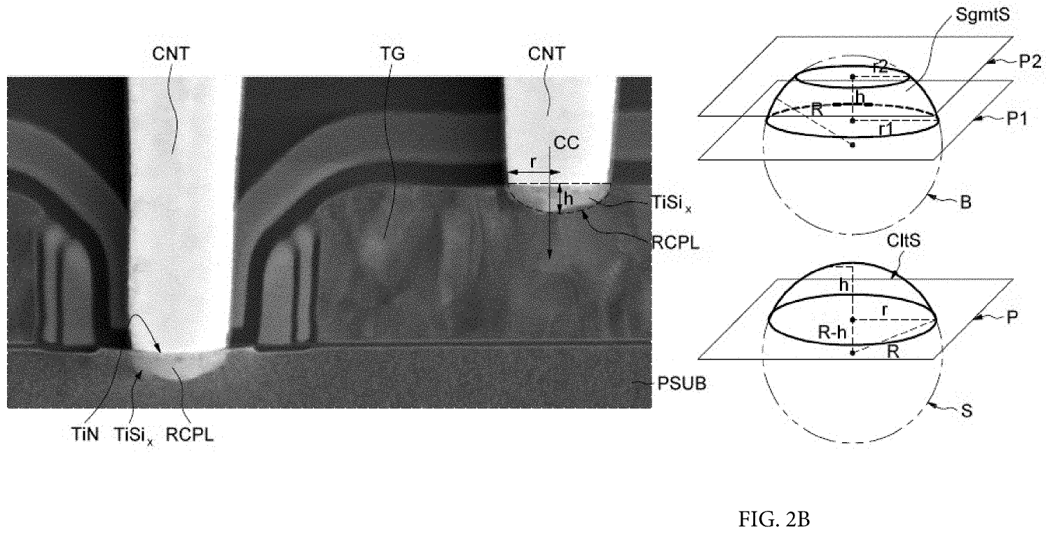

FIG. 3 illustrates a comparative table between certain structural parameters of the devices P1, P2, P3 obtained by the method 200 (FIGS. 2A, 2B and 2C) compared with devices ref1, ref2 obtained by the reference method 100 (FIGS. 1A, 1B, 1C), in particular according to configurations of the annealing steps 108, 208.

The data presented in the table are mean values of measurements of the structural parameters of the ohmic coupling region of a finished product. The structural parameters presented are: the thickness of the layer of silicon nitride TiN; the thickness of the layer of titanium silicide TiSiₓ; the height h of the volume of the ohmic coupling region (i.e. the height of a volume with a cylindrical appearance for ref1, ref2 and the height h of the volume with the appearance of a spherical cap or segment for P1, P2, P3); the silicon atom content in the layer of titanium silicide Si∈TiSiₓ; and the oxygen atom content in the layer of titanium silicide O∈TiSiₓ.

The annealing step 108 of the manufacture of the first reference products ref1 was implemented at a temperature of 715° C. for a period of 5 s.

The annealing step 108 of the manufacture of the second reference products ref2 was implemented at a temperature 715° C. for a period of 15 s.

The annealing step 208 of the manufacture of the first product P1 was implemented at a temperature of 715° C. for a period of 15 s.

The annealing step 208 of the manufacture of the second product P2 was implemented at a temperature of 765° C. for a period of 15 s.

The annealing step 208 of the manufacture of the third product P3 was implemented at a temperature of 790° C. for a period of 15 s.

It can be seen on the mean data of the table that the increase in the temperature of the annealing 208 results in an increase of the height h of the spherical cap or segment RCPL of 15.8 nm, 18.8 nm and 25 nm, or more broadly between 14 nm and 26 nm. It should be noted, however, that the thickness of silicon nitride TiN is substantially constant and similar to the reference products ref1, ref2, between 5.3 nm and 5.6 nm, while the thickness of titanium silicide TiSiₓ increases with the annealing temperature, of 9.5 nm, 13.5 nm and 19.4 nm. Thus, the step of depositing atomic layers of titanium nitride 206 and the annealing 208 would appear to contribute mainly to the obtaining of better isotropy, a greater extent and better uniformity of the diffusion of the metal silicide, represented by the spherical segment or spherical cap appearance of the volume of the ohmic coupling region RCPL.

Furthermore, the silicon content (as atomic percentage) also increases with the increase in the annealing temperature of 60.2%, 72.9% and 78.5%, or more broadly between 60% and 80%. In parallel, the oxygen content is always very low in the products P1, P2, P3, at 6.6%, 5.3% and 4.5% (i.e., below 10% or even below 5%).

These various structural parameters are linked and represent the improvement in the quality of the ohmic coupling region RCPL, and are furthermore particularly advantageous in the context of the production of photosensitive pixels.

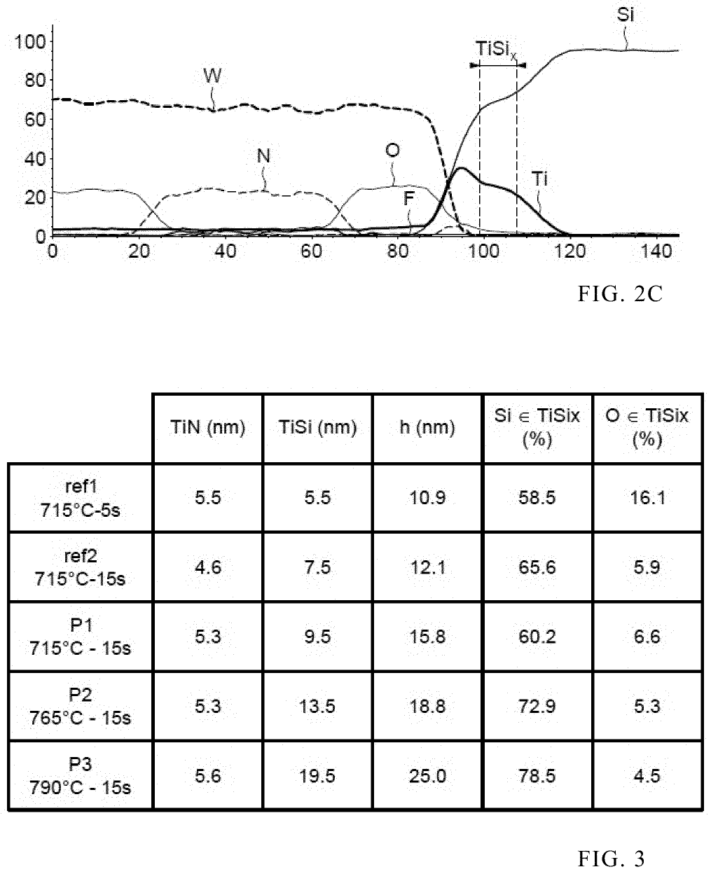

Reference is made in this regard to FIG. 4.

FIG. 4 illustrates schematically a photosensitive pixel PX, usually belonging to a matrix of pixels MPX, for example in an image capture device.

A photosensitive pixel PX includes a photosensitive semiconducting region, for example a pinned photodiode PPD, including a pn junction between the p-type substrate PSUB, particularly made from silicon, and an n-type doped well CN. The well CN of the pinned photodiode PPD forms a cathode region completely deserted by the presence of a highly doped p⁺ region AP+ (i.e., type p doped with a concentration of dopant greater than 10¹⁸ cm⁻³), implanted in a shallow manner in the well CN on the surface of the substrate PSUB.

The pixel PX may furthermore include elements for reading photogenerated charges at the pn junction, such as a transfer gate TG, a transfer node DN+ and optionally a “photogate” TRG or MOS transistors (metal oxide semiconductor, conventional and known per se).

The transfer gate TG is comparable to an MOS transistor gate, produced from polycrystalline silicon on a layer of gate oxide, except that a transfer gate TG is not associated with conduction regions strictly speaking. The transfer gate TG makes it possible to reduce a potential barrier between the diode and for example the transfer node DN+, to make the photogenerated charges migrate without generating any current.

The transfer node DN+ is, for example, produced in the form of an n⁺ doped region (i.e., type n doped at a concentration above 10¹⁸ cm⁻³), in a type n doped well NW.

The term “photogate” corresponds to a buried vertical gate TRG of a transistor, extending vertically in depth in the substrate PSUB. The buried vertical gate transistor TRG fills a trench with a volume of polycrystalline silicon in a dielectric envelope.

Thus, the photosensitive pixel PX and the matrix of photosensitive pixels MPX include at least one silicon region from: transfer gates TG of a transfer transistor; transistor gates (structurally similar to the transfer gate TG); buried vertical gates TRG of a buried transistor; implanted regions AP+ of the p⁺ type; and implanted regions DN+ of the n⁺ type; for example according to the technology of the pixels PX.

These various regions of silicon TG, TRG, n⁺, p⁺, can each be intended to be contacted by a metal pillar CNT on the ohmic coupling region RCPL comprising titanium silicide in a volume having the appearance of a spherical cap or segment, as described previously in relation to FIGS. 2A, 2B, 2C and 3.

This is because the ohmic coupling region RCPL has performance in terms of resistance and reliability adapted to the constraints of the latest imager technologies. In particular, the performances of the ohmic coupling regions RCPL help to reduce the dark current of the pixels PX. The dark current is a parasitic current generated by the photodiode PPD in the absence of light.

Moreover, the ohmic coupling regions RCPL have performance in terms of resistance and reliability adapted to the constraints of the latest three-dimensional integration technologies of two superimposed chips, for example for images of the 3D-BSI type.

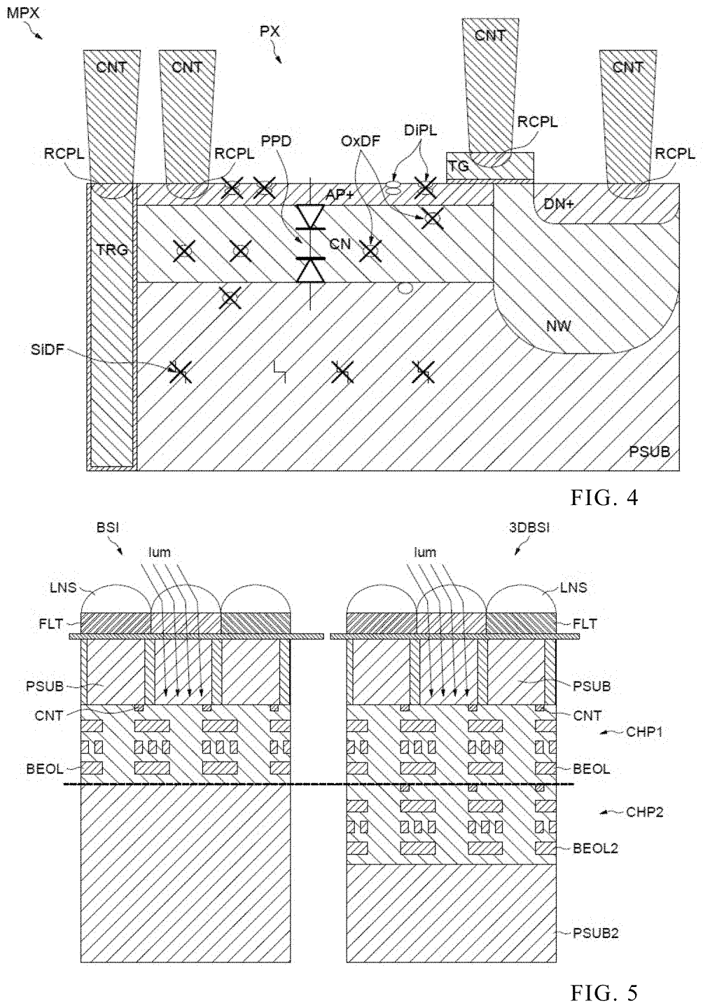

Reference is made in this regard to FIG. 5.

FIG. 5 illustrates a backside illumination BSI imager technology, and a backside illumination BSI imager technology in a three-dimensional integration of two superimposed chips 3D-BSI.

The backside illumination BSI imager includes a matrix of photosensitive pixels of the same type as the matrix MPX described in relation to FIG. 4. The rear face of the substrate PSUB including the matrix MPX is intended to receive a flow of light lum and is covered in this regard with an array of lenses LNS and of filters FLT, typically red, green and blue.

The metal pillars CNT in contact, on the ohmic coupling regions RCPL, with the various silicon regions TG, TRG, N+, P+, belong to an interconnections part BEOL.

In the backside illumination imager technology in a three-dimensional integration of two superimposed chips 3D-BSI, a first chip CHP1, substantially identical to the backside illumination BSI imager device, is assembled with a second chip CHP2, at the respective interconnection parts BEOL, BEOL2 thereof. The substrate PSUB2 of the second chip CHP2 may, for example, include high-performance circuits for processing the image signals, without increasing the size, in terms of surface area, of the global device 3DBSI.

The three-dimensional backside illumination technology 3D-BSI introduces greater requirements in terms of performance of the contacts CNT, RCPL to meet the requirements of the products, which are of higher performance. And the ohmic coupling regions RCPL described above in relation to FIGS. 2A, 2B, 2C, 3 and 4 are compatible with the requirements of the backside illuminated three-dimensional backside illuminated technologies 3D-BSI.

Furthermore, it was serendipitously discovered by the inventors that manufacturing the coupling regions RCPL according to the method 200 described in relation to FIG. 2A makes it possible to reduce, much more than expected, the dark current of the imager device using which this manufacture 200 is implemented.

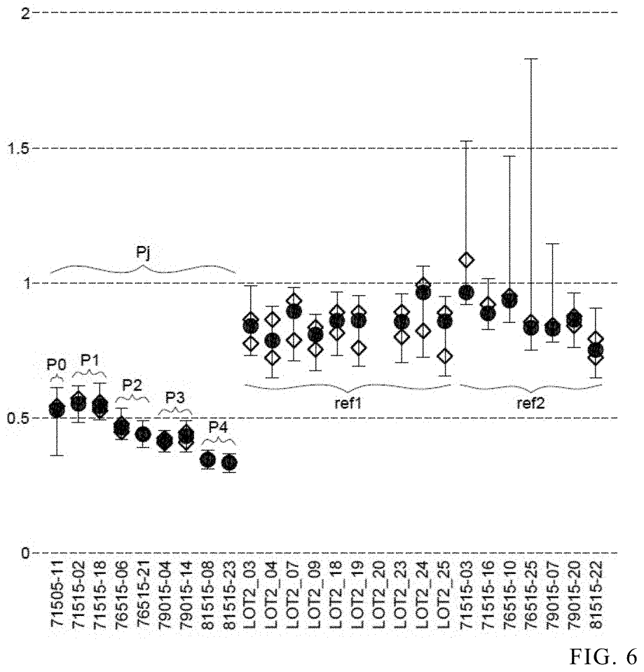

In this regard reference is made to FIG. 6.

FIG. 6 illustrates measurements of the dark current of the pixels for imager devices Pj comprising coupling regions RCPL manufactured in accordance with the method 200, and for imager devices identical from the point of view of the pixels, but comprising coupling regions RCPL manufactured in accordance with the reference method 100, ref1, ref2, as described previously in relation to FIG. 3.

The scale of the dark current (on the x axis) is standardized by an index without any dimension, the worst case of the reference imager devices ref1, ref2 being positioned at index 1. All the measurements of the dark current of the reference imager devices ref1, ref2 are close to 1, approximately between 0.75 and 1.

The measurements of the dark current of the imager devices Pj manufactured with the method 200 are for their part close to the index 0.5, approximately between 0.3 and 0.55. The dark current is thus substantially divided by 2 compared with the reference methods ref1, ref2.

The devices of the populations P1, P2, P3 are manufactured under the conditions described previously in relation to FIG. 3.

The devices of the population P0 are manufactured with annealing conditions 208 of the method 200 described in relation to FIG. 2A that correspond to the annealing conditions 108 of the reference method 100 (i.e., a temperature T of 715° C. for a time t of 5 s).

The devices of the population P4 are manufactured with annealing conditions 208 of the method 200 described in relation to FIG. 2A, at a temperature T of 815° C. for a time t of 15 s.

The reduction in the dark current is greater with the increase in the temperature T, but there is a risk, in particular above 800° C., of degrading or even functionally destroying the photosensitive diodes PPD.

Thus, preferential conditions of the annealing step 208 of the method 200 described in relation to FIG. 2A are a temperature T of 765° C. for a time t of 15 s, and a temperature T of 790° C. fora time t of 15 s.

As mentioned previously, the reduction in the dark current results in particular from the improvement in the quality of the ohmic coupling region RCPL, in particular with regard to reducing the resistive value of the coupling.

That being the case, it is considered that this magnitude of the reduction in the dark current (division by 2) stems from other additional physical phenomena, related to the ohmic coupling region RCPL, and to the implementation of the steps of the method 200 described in relation to FIG. 2A.

Reference is made in this regard once again to FIG. 4.

It is considered in fact that three other phenomena can contribute to reducing the dark current, in addition to the reduction in the resistance of the ohmic coupling region RCPL.

Firstly, there are dipoles DiPL in defects located at the interface between the substrate PSUB, i.e. the surface of the highly doped region AP+, and the pre-metal dielectric layer that covers it (not shown). These dipoles contribute to the generation of current leakages in the pn junction of the PPD diode, forming part of the dark current. However, it is possible and probable that the electrostatic holding plate ElStCh used in the step 204 of depositing the layer of titanium of the method 200 described in relation to FIG. 2A makes the electrical dipoles in the interface defects disappear under the influence of the electrical fields (+/−400 V) generated by the plate ElStCh.

Secondly, there are crystalline defects caused by oxygen atoms OxDF, for example coming from the migration of oxygen in the doped regions CN, PSUB of the diode PPD, which also contribute to the generation of current leakages in the pn junction of the diode PPD forming part of the dark current. However, as mentioned previously, the technique of atomic layer deposition ALD of step 206 of the method 200 described in relation to FIG. 2A makes it possible to form a dense titanium nitride layer, rich in nitride, and depleted in impurity, with in particular an oxygen content below 10%, or even below 5%, or even below 3%. It is possible and probable that the low oxygen content in the ohmic coupling regions RCPL results in a smaller quantity of oxygen atoms migrating into the silicon regions of the substrate CN, PSUB and therefore in a smaller quantity of defects OxDF.

Thirdly, there are so-called “mechanical” crystalline defects SiDF caused, for example, by etching operations in the substrate PSUB, by changes in temperatures in the presence of materials having different coefficients of expansion, by phenomena of migration of the silicon atoms in the crystalline lattice, or by other causes; which also contribute to the generation of current leakages in the pn junction of the diode PPD and to the dark current. However, it is possible and probable that the conditions of the annealing step 208 of the method 200 described in relation to FIG. 2A, at a higher temperature T for a longer time t, make it possible to “repair” the crystalline defects by diffusion of the silicon and by redistribution of the doping species in the crystalline lattice of the silicon PSUB, CN.

1. An integrated circuit, comprising:
at least one silicon region; and
at least one metal pillar in contact with said silicon region at an ohmic coupling region;
wherein the ohmic coupling region comprises titanium silicide including oxygen atoms in proportions below 10% and silicon atoms in proportions in a range from 60% to 80%.

2. The integrated circuit according to claim 1, wherein the ohmic coupling region has a volume defined by a spherical segment.

3. The integrated circuit according to claim 2, wherein the spherical segment has a first base disc radius in a range of 45 nanometers to 57 nanometers, and a height in a range of 14 nanometers to 26 nanometers.

4. The integrated circuit according to claim 1, wherein the ohmic coupling region comprises:
a layer of titanium nitride; and
a layer of titanium silicide;
wherein a thickest part of the layer of titanium nitride has a thickness of between 5 nanometers and 6 nanometers; and
wherein a thickest part of the layer of titanium silicide has a thickness of between 9 nanometers and 20 nanometers.

5. The integrated circuit according to claim 1, further including a matrix of photosensitive pixels, wherein the at least one silicon region is located in the matrix of photosensitive pixels.

6. The integrated circuit according to claim 5, wherein said matrix of photosensitive pixels includes a transistor having a gate region, and wherein the at least one silicon region is the gate region of the transistor.

7. The integrated circuit according to claim 6, wherein the transistor comprises one of a transfer transistor or a vertical transistor buried in a substrate.

8. The integrated circuit according to claim 1, wherein the at least one silicon region is p⁺ doped silicon with a concentration of p dopants greater than or equal to 10¹⁸ atoms per cubic centimeter.

9. The integrated circuit according to claim 1, comprising an assembly in a three-dimensional integration of two superimposed integrated circuit chips.

10. A method for manufacturing an integrated circuit, comprising:
forming at least one silicon region; and
forming at least one metal pillar in contact with said at least one silicon region at an ohmic coupling region;
wherein forming the at least one metal pillar comprises:
depositing a layer of titanium on the at least one silicon region;
depositing an atomic layer of titanium nitride on the layer of titanium; and
annealing at a temperature in a range of 715° C. to 815° C. for a period of time in a range of 5 seconds to 30 seconds to form an ohmic coupling region of titanium silicide.

11. The method according to claim 10, wherein the ohmic coupling region of titanium silicide has a volume defined by a spherical segment.

12. The method according to claim 10, wherein forming the at least one metal pillar comprises performing a surface preparation on the at least one silicon region using a remote gas plasma of nitrogen trifluoride and ammonia, wherein performing the surface preparation is performed before depositing the layer of titanium.

13. The method according to claim 10, wherein the layer of titanium has a thickness in a range of 17.5 nanometers to 40 nanometers, and wherein the layer of titanium nitride has a thickness in a range of 3 nanometers to 6 nanometers.

14. The method according to claim 10, wherein forming said at least one silicon region is performing during manufacture of a matrix of photosensitive pixels.

15. The method according to claim 14, wherein depositing the layer of titanium comprises using an electrostatic plate to hold a semiconductor wafer including the integrated circuit.

16. The method according to claim 14, wherein manufacture of the matrix of photosensitive pixels comprises forming a transistor having a gate, and wherein said at least one silicon region is the gate of the transistor.

17. The method according to claim 16, wherein transistor is one of a transfer transistor or a vertical transistor buried in a substrate.

18. The method according to claim 10, wherein forming the at least one silicon region comprises implanting p-type dopants in silicon with a concentration greater than or equal to 10¹⁸ atoms of dopant per cubic centimeter.

19. The method according to claim 10, further comprising assembling the integrated circuit as a three-dimensional integration of two superimposed integrated circuit chips.

20. The method according to claim 10, wherein the ohmic coupling region of titanium silicide includes oxygen atoms in proportions below 10% and silicon atoms in proportions in a range of 60% to 80%.
